(19) United States
(12) Patent Application Publication
(10) Pub. No.: US 2016/0293785 A1
(43) Pub. Date: Oct. 6, 2016

(54) SOLAR CELL AND MANUFACTURING METHOD OF BACK ELECTRODES THEREOF

(71) Applicant: NEO SOLAR POWER CORP., Hsinchu City (TW)

(72) Inventors: Shan-Chuang PEI, Hsinchu City (TW); Shao-Wei HUANG, Hsinchu City (TW); Wei-Chih HSU, Hsinchu City (TW)

(73) Assignee: NEO SOLAR POWER CORP., Hsinchu City (TW)

(21) Appl. No.: 15/085,202

(22) Filed: Mar. 30, 2016

(30) Foreign Application Priority Data
Apr. 2, 2015 (TW) 104111042

(51) Int. Cl. H01L 31/0224; H01L 31/0216

(52) U.S. Cl. CPC H01L 31/022441; H01L 31/02168

(57) ABSTRACT

A solar cell and manufacturing method of back electrodes thereof are disclosed. The method includes a step of implementing a screen printing process to a semiconductor substrate. The method also includes a step of measuring a deviation which exists between laser ablation recesses and back electrodes in the screen printing process. The method further includes a step of adjusting the distance between the laser ablation recess and the back electrode according to the deviation. After adjusting, a deviation between laser ablation recesses and back electrodes will be controlled to a narrower range when the screen printing process is implemented to another semiconductor substrate. Thus, the defect is caused by the back electrodes incompletely covering the laser ablation recesses can be improved significantly.

### CROSS-REFERENCES TO RELATED APPLICATIONS

This non-provisional application claims priority under 35 U.S.C. §119(a) on Patent Application No. 104111042 filed in Taiwan, R.O.C. on 2015/04/02, the entire contents of which are hereby incorporated by reference.

### BACKGROUND

1. Technical Field

The instant disclosure relates to a solar cell and a manufacturing method of back electrodes thereof.

2. Related Art

Solar cells currently are the most widely used and developed green energy. To enhance electricity generation efficiency and reduce its generating cost, various types of solar cell have been developed. Solar cells roughly can be divided into three types: silicon solar cells; compound semiconductor solar cells; and organic solar cells. In particular, silicon solar cells are the most developed and widely used type, with the single crystal silicon solar cells having highest conversion efficiency among all of the solar cells.

Currently ten plus types of silicon solar cells with high conversion efficiency have already been known. Among those for mass commercial production roughly includes the hetero-junction with intrinsic thin layer (HIT) solar cells, interdigitated back contact (IBC) solar cells, bifacial solar cells, and passivated emitter rear locally diffused cell (PERL).

When fabricating bifacial or PERC solar cells, laser ablation technique is used for etching the antireflection layer and passivation layer on the backside of the cells. Thus, the semiconductor layer underneath the passivation layer can be exposed, with the resulting openings typically of elongated shape and spaced apart from one another. Next, based on the screen-printing technique, the pre-formulated aluminum paste is scraped into the openings obtained by laser ablation. Then, the aluminum paste undergoes a firing process to form multiple fence-shaped back electrodes at the back side of the solar cells.

Before printing the aluminum paste, the screen pattern has to align with the pattern defined by the openings, which are formed by laser ablation. Without considering the tolerances of the screen printing machine itself, material fatigue tends to occur after the screen has been used for a prolonged period or after repeated use. Consequently, misalignment between the back electrodes and the etched holes (by laser ablation) may happen. Please refer to FIG. 1, which is a first schematic view showing the misalignment condition. As shown, the back electrodes 91 are adversely misalignment from the laser ablated holes 92, yet the back electrodes 91 are still able to completely cover the laser ablated holes 92. If the misalignment is minor, that is to say the back electrodes 91 are still able to completely cover the laser ablated holes 92, such issue does not significantly affect the conversion efficiency of the solar cells. Next, please refer to FIG. 2, which is a second schematic view showing another misalignment condition. When the misalignment error is to the point where the back electrodes 91 do not completely cover the laser ablated holes 92, even if only a few laser ablated holes 92 aren't completely covered by the back electrodes 91, the conversion efficiency of the solar cells drops dramatically. In the field of solar cells, since the power generated by solar cell plants is in the range of millions of watts, even a slight dip of 0.1% in conversion efficiency means the total electric power in watts will take a significant drop, which translates to higher cost per watt.

Based on the actual screen-printing practice, the abovementioned misalignment often appears for back electrodes situated on the side regions of the solar cells. The further away the central region is, the more likely the misalignment will occur, and the extent of misalignment is more severe.

### SUMMARY

The instant disclosure provides a manufacturing method of back electrodes of a solar cell, which comprises the steps of: (a) providing a semiconductor substrate doped with a first type dopant, where the semiconductor substrate has a first surface and a second surface opposite thereto, and the first surface defines at least m number of first openings and m being an integer greater than 1, with the first openings arranged alternately along an X axis direction, and the centers between adjacent first openings are separated by a first distance a; (b) providing a screen, which defines at least m number of screen holes alternately arranged along the X axis direction, with the centers of adjacent screen holes being substantially separated by the first distance a, and the m number of screen holes corresponding to respective first openings; (c) forming at least m number of back electrodes on the first surface via the screen; (d) measuring a largest distance s defined along the X axis direction between the centers of the back electrodes and the centers of the first openings underneath; and (e) adjusting a distance between the centers of adjacent first openings of another semiconductor substrate to be a second distance b according to the largest distance s, with the second distance b being greater than the first distance a.

In one embodiment, the second distance b satisfies

$$b = a + \frac{2 s}{( m - 1 )} .$$

In one embodiment, the first surface of the other semiconductor substrate defines a central region and at least two side regions, with the two side regions arranged on opposite sides of the central region, where in step (e) the distance between the centers of adjacent first openings of the two side regions is adjusted to the second distance b.

In one embodiment, the central region extends along a Y axis direction to an edge of the other semiconductor substrate, with the two side regions arranged along the X axis direction on opposite sides of the central region, wherein the surface area of the central region occupies one tenth to one third of the surface area of the first surface.

In one embodiment, the first surface defines a center line parallel to the Y axis direction, and the second distance b increases further away from the center line.

In one embodiment, the first surface defines a center line parallel to the Y axis direction, with the second distance b ranging from 500 to 2500 μm.

The instant disclosure also provides a solar cell, which comprises: a semiconductor substrate doped with a first type dopant, where the substrate has a first surface and a second surface opposite thereto; a first passivation layer disposed on the first surface, where the first passivation layer defines m number of first openings, with m being an integer greater than 1, and the first openings are alternately arranged along an X axis direction; a first anti-reflection layer disposed on the first passivation layer, the first anti-reflection layer defines m number of second openings corresponding to respective m number of first openings; a plurality of back surface field regions at the first surface and corresponding to respective m number of first openings, where the concentration of the first type dopant of the back surface field regions being greater than that of the first type dopant of the semiconductor substrate; a plurality of back electrodes alternately arranged along the X axis direction, with the back electrodes making electrical contact with respective back surface field regions via m number of second openings and m number of first openings, where any of the back electrodes defines a first center line along a Y axis direction, with the first openings corresponding to the back electrodes each defining a second center line along the Y axis direction, and the first center line and the second center line are separated by a distance less than 250 μm; a second doping layer disposed on the second surface, where the second doping layer is doped with a second type dopant; a second passivation layer disposed on the second doping layer and defines a plurality of third openings; a second anti-reflection layer disposed on the second passivation layer, with the second anti-reflection layer defining a plurality of fourth openings corresponding to the third openings; and a plurality of front electrodes making electrical contact with the second doping layer via respective third and fourth openings.

In one embodiment, the first surface of the semiconductor substrate of the solar cell defines a third center line parallel to the Y axis direction, with the second center lines of adjacent first openings being separated by a second distance b, and the second distance b ranges from 500 to 2500 μm.

In one embodiment, the first surface of the semiconductor substrate of the solar cell defines a third center line parallel to the Y axis direction, with the second center lines of adjacent first openings being separated by a second distance b, and the second distance b increases further away from the third center line.

In one embodiment, the first surface of the semiconductor substrate of the solar cell defines a third center line parallel to the Y axis direction and a central region and at least two side regions. The central region extends along the Y axis direction to the edge of the semiconductor substrate, where the two side regions are arranged along the X axis direction on opposite sides of the central region, and where the surface area of the central region occupies one tenth to one third of the surface area of the first surface, with the second center lines of adjacent first openings of the two side regions being separated by a second distance b.

In one embodiment, the second distance b ranges from 500 to 2500 μm.

In one embodiment, the second distance b increases further away from the third center line.

### BRIEF DESCRIPTION OF THE DRAWINGS

FIG. 1 is a first schematic view showing the misalignment in the prior art.

FIG. 2 is a second schematic view showing the misalignment in the prior art.

FIG. 3 is a flowchart illustrating the manufacturing method of back electrodes of a solar cell of the instant disclosure.

FIG. 4 is a first schematic view illustrating the manufacturing process with a screen of the instant disclosure.

FIG. 5 is a first top view illustrating the back electrodes of the solar cell of the instant disclosure.

FIG. 6 is a second schematic view illustrating the manufacturing process with the screen of the instant disclosure.

FIG. 7 is a second top view illustrating the back electrodes of the solar cell of the instant disclosure.

FIG. 8 is a first sectional view of the solar cell of the instant disclosure.

FIG. 9 is a third top view illustrating the back electrodes of the solar cell of the instant disclosure.

FIG. 10 is a second sectional view of the solar cell of the instant disclosure.

### DETAILED DESCRIPTION

The manufacturing method of back electrodes of a solar cell of the instant embodiment is explained hereinbelow. It should be noted that the steps described in sequence below are not used to restrict the implementation sequence of the instant embodiment.

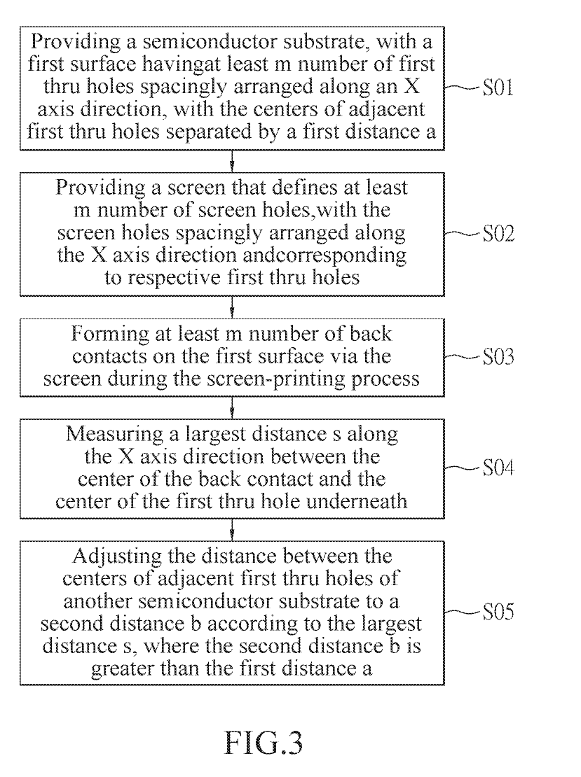

Please refer to FIGS. 3 to 5, which are the flow chart of the manufacturing method of back electrodes of a solar cell of the instant disclosure, a first schematic view of the manufacturing process with a screen, and a first top view of back electrodes of the solar cell, respectively. A semiconductor substrate 101 is provided in step S01. The semiconductor substrate 101 is doped with a first type dopant (e.g., p-type dopant). The semiconductor substrate 101 has a first surface 1011 and a second surface 1012 opposite thereof. As a final product after processing, for the solar cells, the second surface 1012 is utilized as a light-receiving surface, while the first surface 1011 is a light-receiving or non-light-receiving surface. As shown in FIG. 3, a first passivation layer 103 is formed on the first surface 1011, and a first anti-reflection layer 104 is formed on the first passivation layer 103. By laser ablation, at least m number of first openings 103a can be formed on the first passivation layer 103, which on the first surface 1011. In practice, the first openings 103 may be solid-line openings, dashed-line openings, dotted openings, or any combination thereof (e.g., dash dotted openings). Meanwhile, the first anti-reflection layer 104 defines at least m number of second openings 104a, where m is an integer greater than one. The opening size of each first opening 103a and second opening 104a is the same, and all of the holes are alternately arranged along an X axis direction, where the centers of adjacent first openings 103a are separated by a first distance a. The X axis direction is different from the extended directions of first openings 103a and second openings 104a.

For step S02, a screen 99 for screen-printing is provided. The screen 99 is defined with at least m number of screen holes 99a corresponding to respective first openings 103a. The screen holes 99a are alternately arranged along the X axis direction.

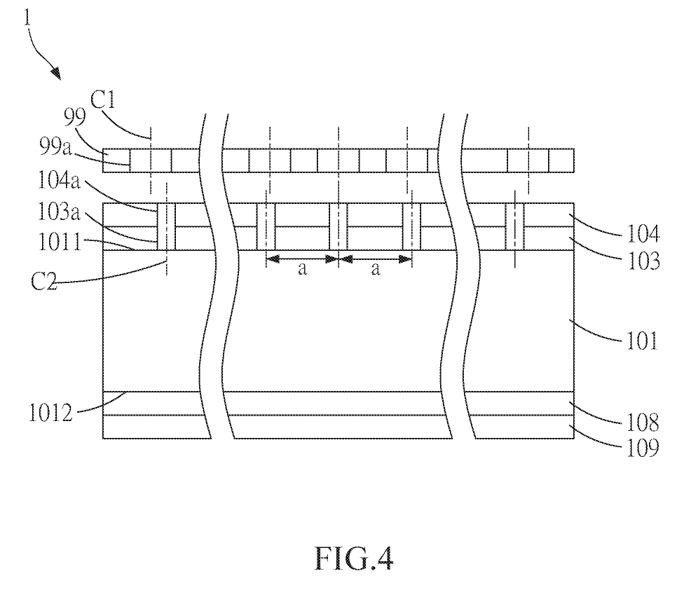

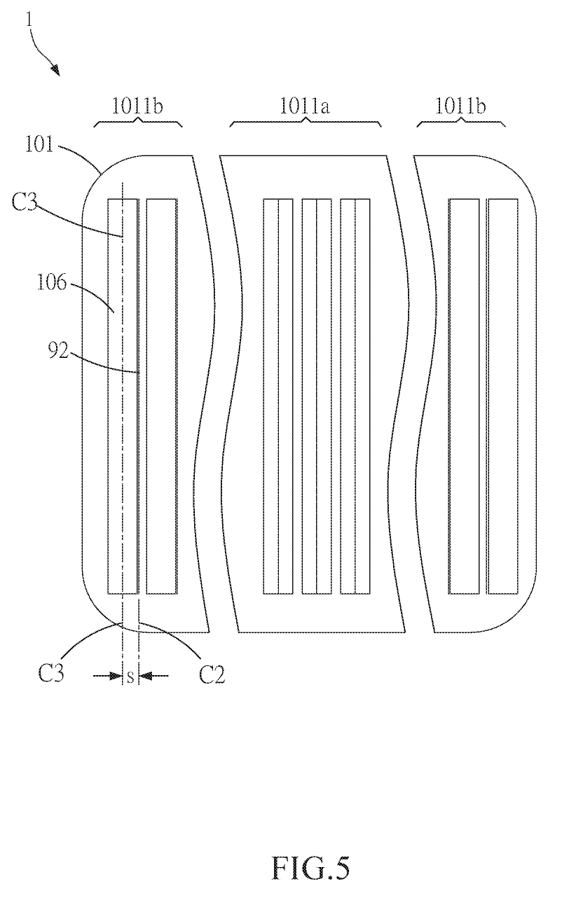

Step S03 is to scrape the aluminum paste into the first and second openings 103a and 104a via the screen 99 during screen-printing process. Then, an aluminum paste firing process is performed to form at least m number of back electrodes 106 on the first surface 1011, as shown in FIGS. 4 and 5.

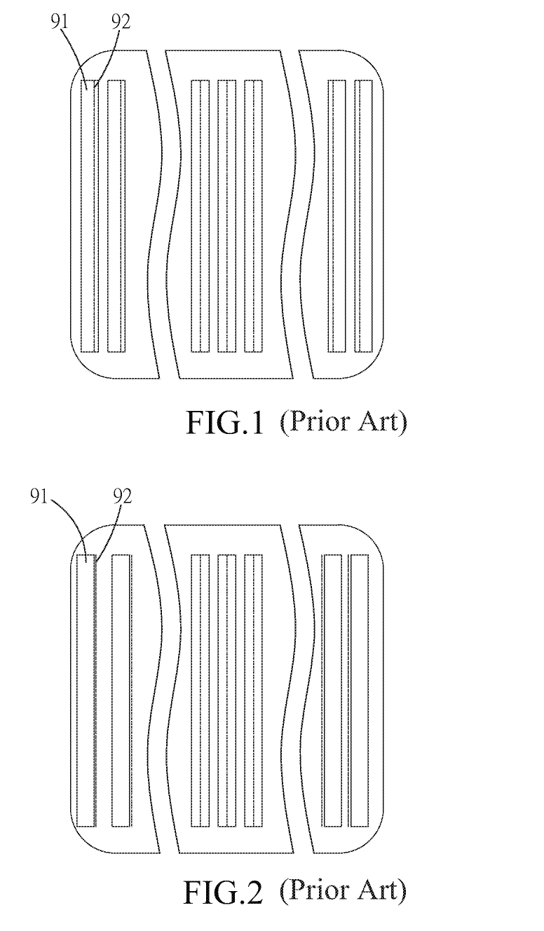

Step S04 is to measure the largest distance between the center C3 of the back electrode 106 and the center C2 of the first opening 103a, which is arranged along the X axis direction and under the back electrode 106. Under normal circumstances, the distance between any two adjacent screen holes 99a of the screen 99 substantially equal to the first distance a between the centers of two adjacent first openings 103a. Via screen-printing, although the distance between two adjacent back electrodes 106 does not directly equal to the first distance a, but usually each back electrode 106 is sufficient to cover the corresponding first opening 103a underneath, as shown in FIG. 1. However, when material fatigue occurs due to extended use of the screen 99, the distance between two adjacent screen holes 99a of the screen 99 changes, which leads to misalignment. As illustrated in FIG. 4, the center C1 of the screen hole 99a and the center C2 of the first opening 103a are misalignment from each other. Hence, via screen-printing, the center C3 of the back electrode 106 and the center C2 of the first opening 103a underneath are also misalignment from each other, as shown in FIG. 5. As a result, some of the back electrodes 106 do not completely cover the corresponding laser ablated holes 92 underneath (i.e., the first and second openings 103a and 104a in FIG. 4). The further away the center of the first surface 1011 is, the more severe the level of misalignment. In other words, the extent of misalignment is relatively less for a central region 1011a of the first surface 1011 of a solar cell 1, while the misalignment is more severe for two side regions 1011b on opposite sides of the central region 1011a. As shown in FIG. 5, the largest distance S between the center C3 of the back electrode 106 and the center C2 of the underlying first opening 103, which are arranged along the X axis direction, occurs at the outer edge portion of the semiconductor substrate 101.

The above described steps are mainly for evaluating the largest misalignment distance between the back electrodes 106 of the semiconductor substrate 101 and the laser ablated first openings 103a, during the formation of the back electrodes 106 on the first surface 1011 of the semiconductor substrate 101 via the screen 99. That is to say the largest distance s between the center C3 of the back electrodes 106 and the center C2 of the first opening 103a along the X axis direction. Next, in step 505, the distance between adjacent etched holes during the laser ablation process is adjusted according to the largest distance s. In other words, the original first distance a between adjacent first openings 103a is adjusted to a second distance b, where b>a. In addition, as shown in FIG. 4, the manufacturing method of back electrodes of the solar cell 1 for the instant embodiment, a second passivation layer 108 and a second anti-reflection layer 109 can further be formed over the second surface 1012.

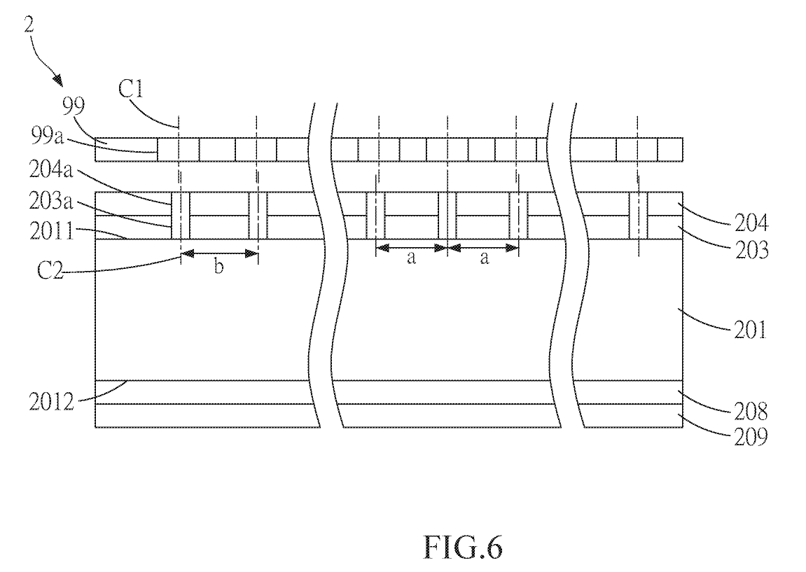

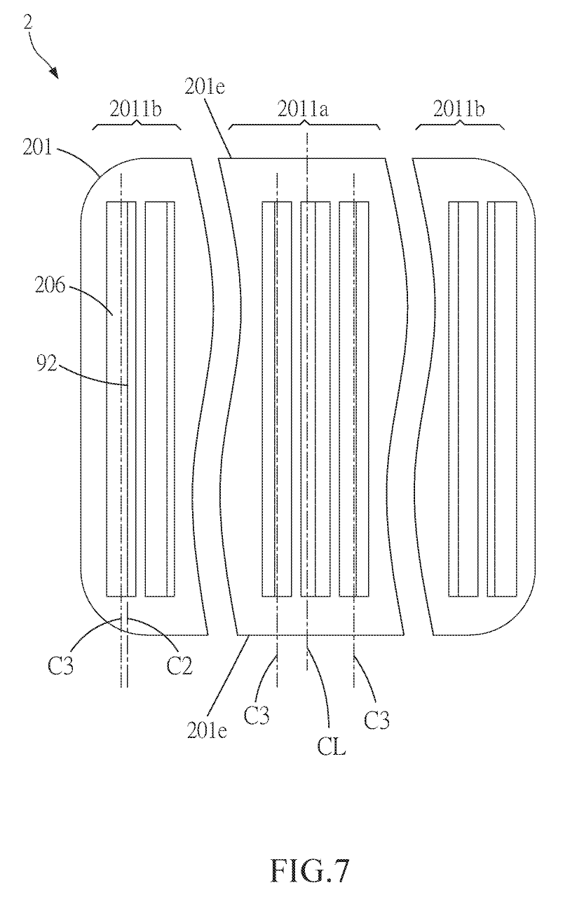

Please refer to FIGS. 6 and 7, which are a second schematic view of the screen manufacturing process and a second top view of back electrodes of solar cell of the instant disclosure, respectively. After the largest misalignment has been confirmed by using the screen 99 to perform screen-printing, that is to measure the largest distance s between the center C3 of the back electrode 106 and the center C2 of the underlying first opening 103a along the X axis direction, the distance between each laser scribing during the laser ablation process can be adjusted according to the largest distance s. Now, another semiconductor substrate, which is labeled as 201 and will be processed to form the actual solar cell product, is utilized. This element is structurally the same as the semiconductor substrate 101 in general. Using laser ablation, a plurality of first openings 203a and second openings 204a are formed on a first passivation layer 203 and a first anti-reflection layer 204, respectively, with the first passivation layer 203 and first anti-reflection layer 204 disposed over a first surface 2011 of the semiconductor substrate 201. However, the distance between the centers C3 of adjacent first openings 203a is no longer the original first distance a but is the second distance b instead, with b>a. Thus, the centers of the first openings 203a are more aligned with the centers of the screen holes 99a. Consequently, when forming the back electrodes 206, the back electrodes 206 more easily cover the first and second openings 203a and 204a, such that the probability of improper manufacturing with the back electrodes 206 not completely covering the first and second openings 203a and 204a is reduced. As illustrated in FIG. 7, the back electrodes 206 of an adjusted solar cell 2 fully cover the laser ablated holes 92 underneath (i.e., the first and second openings 203a and 204a). It should be noted that the back electrodes 206 of a solar cell 2 has a unique characteristic that the distances between the centers C3 of the back electrodes 206 of a central region 2011a and respective centers C2 of the underlying first and second openings 203a and 204a are slightly increased than before. In other words, without the adjustment, the centers C3 of the back electrodes 206 of the central region 2011a may overlap or are very close to overlap respective laser ablated holes 92 underneath. However, after the adjustment is made, the centers C3 of the back electrodes 206 of the central region 2011a are further misalignment from respective centers C2 of the underlying first and second openings 203a and 204a. The reason being originally, significant misalignment between the centers C3 of the back electrodes 206 of the central region 2011a and respective centers C2 of the first and second openings 203a and 204a underneath are less likely to occur. Hence, misalignment condition gets slightly worse after the adjustment is made. Nevertheless, as previously mentioned, as long as the back electrodes 206 completely cover the laser ablated holes 92, the presence of misalignment does not inflict significant adverse effect with regard to conversion efficiency of the solar cell. The abovementioned central region 2011a also extends along a Y axis direction to an edge 201e of the semiconductor substrate 201. Meanwhile, in the X axis direction, at least two side regions 2011b are defined along opposite sides of the central region 2011a. Therefore, the X axis direction is different from the Y axis direction, and the X axis direction crosses the Y direction at any angle. In addition, as shown in FIG. 6, for the manufacturing method of back electrodes of the solar cell 2 for the instant embodiment, a second passivation layer 208 and a second anti-reflection layer 209 can further be formed over a second surface 2012.

The abovementioned technique of adjusting the second distance b depends on the nature of the misalignment, where one type of adjustment technique utilizes the following equation:

$$b = a + \frac{2 s}{( m - 1 )}$$

The above equation calls for multiplying the largest misalignment, which is the largest distance s, by 2. The product is then divided by the number of spaces (m−1) between the first openings 203a on the first surface 2011. The reason for multiplying by 2 is due to the fact that misalignment usually gets worse toward opposite sides of the central region of the first surface 2011. Practically speaking, the largest distance s gradually increases from the center of the first surface 2011 toward the edges thereof. Thus, the largest distance s is defined cumulatively by the (m−1)/2 number of spaces from the center of the first surface 2011 to the outer sides thereof. In other words, the above equation directly divides the largest distance s by (m−1)/2 number of spaces in getting a correction value. Comparing to the first distance a, the corrected second distance b is increased by an amount of

$$\frac{2 s}{( m - 1 )} .$$

Based on the above described adjustment, the probability of improper manufacturing of the back electrodes 206 not completely covering the first and second openings 203a and 204a is reduced from greater than 10% to less than 3%.

Another adjustment technique is based on the fact that most misalignments occur at the side regions 2011b of the first surface 2011. Therefore, only the second distance b between adjacent first openings 203a defined in the side region of the first surface 2011 needs to be adjusted. Meanwhile, the distance between the centers of adjacent first openings 203a in the central region 2011a of the first surface 2011 remains as the first distance a. The surface area of abovementioned central region 2011a ranges from one tenth to one third of the surface area of the first surface 2011. Based on such adjustment, the probability of improper manufacturing of the back electrodes 206 not completely covering the first and second openings 203a and 204a is reduced from greater than 10% to less than 3%.

Yet further still another adjustment technique relates to the misalignment condition that gradually worsens from the center of the first surface 2011 to the edges thereof. Hence, after the adjustment, the second distance b for the distance between the centers of adjacent first openings 203a is not a fixed value, instead increases gradually from the center of the first surface 2011 toward the sides thereof.

The abovementioned gradual increase may be characterized linearly. For instance, assuming the first surface 2011 defines a center line CL. Next, the first opening 203a closest to the center line CL of the first surface 2011 is labeled as numeral 1, with the rest first openings 203a labeled sequentially as numerals 2, 3 . . . n−1, and n in the X axis direction toward the outer edges of the semiconductor substrate 201. Thus, for the distance between the first openings 203a that are labeled 2 and 3 and the distance between the first openings 203a that are labeled 1 and 2, the difference between the two distances are Δs; for the distance between the first openings 203 a that are labeled 3 and 4 and the distance between the first openings 203a that are labeled 2 and 3, the difference between the two distances are Δ2s ; for the distance between the first openings 203a that are labeled 4 and 5 and the distance between the first openings 203a that are labeled 3 and 4, the difference between the two distances are Δ3s; . . . . Based on such approach, for the distance between the outer most first openings 203a that are labeled n−1 and n and the distance between the first openings 203a that are labeled n−2 and n−1, the difference between the two distances are (n−2)Δs. In turn, Δs+2Δs+3Δs+ . . . +(n−2)Δs=largest distance s. In other words, the largest distance s satisfies the following equation:

$$s = {\sum }_{m = 1}^{n - 2} m Δ s .$$

Based on such adjustment, the probability of improper manufacturing of the back electrodes 206 not completely covering the first and second openings 203a and 204a is reduced from greater than 10% to less than 1%.

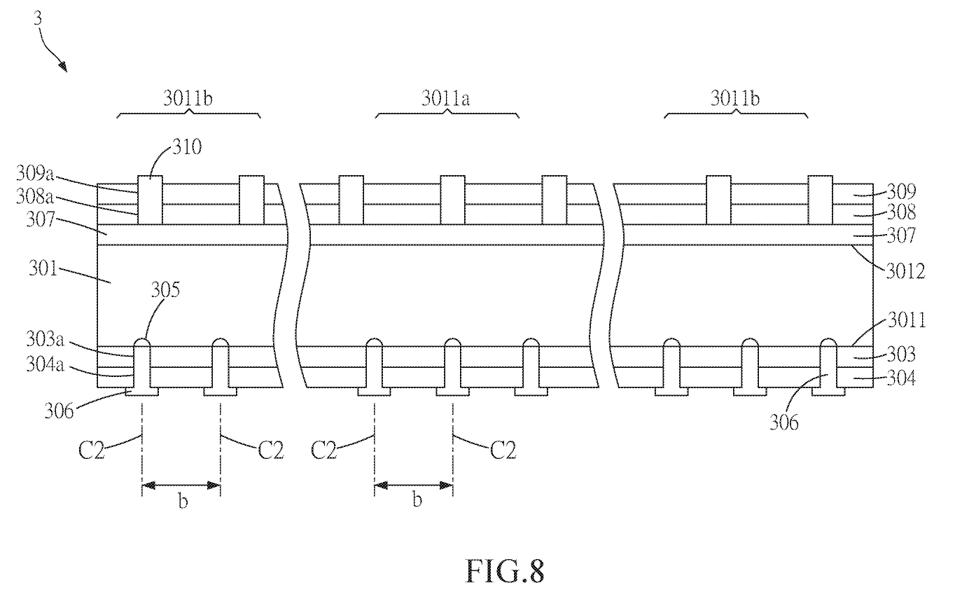

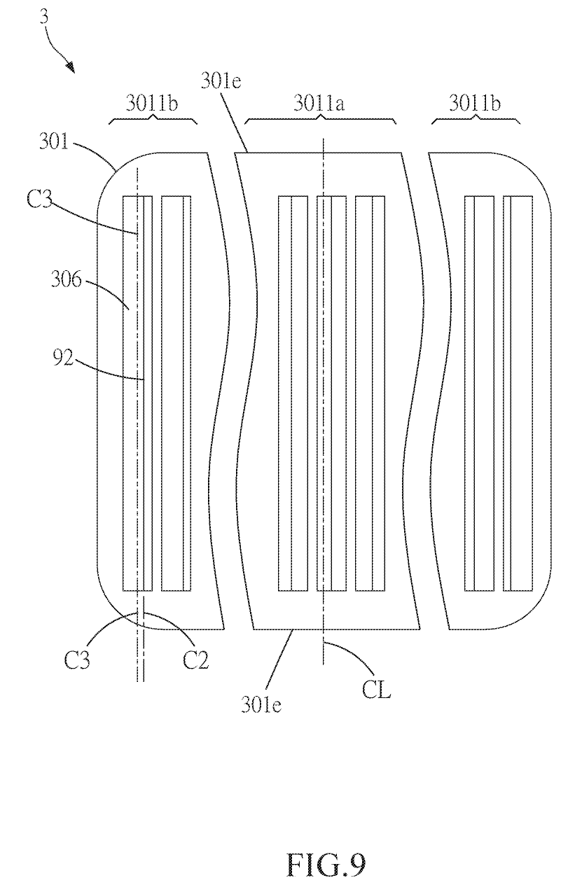

Please refer to FIGS. 8 and 9, which illustrate a first sectional view of the solar cell and a third top view of back electrodes of the solar cell of an embodiment of the instant disclosure, respectively. The figures disclosed a solar cell 3, which comprises a semiconductor substrate 301, a first passivation layer 303, a first anti-reflection layer 304, a plurality of back surface field regions 305, a plurality of back electrodes 306, a second doping layer 307, a second passivation layer 308, a second anti-reflection layer 309, and a plurality of front electrodes 310.

The semiconductor substrate 301 is doped with a first type dopant. For the instant embodiment, the first type dopant is a p-type dopant (e.g., boron of Group IIIA). The semiconductor substrate 301 has a first surface 3011 and a second surface 3012 opposite thereto.

The first passivation layer 303 is disposed on the first surface 3011 and defines m number of first openings 303a, where m is an integer greater than 1. Each of the first openings 303a is alternately arranged along the X axis direction.

The first anti-reflection layer 304 is disposed on the first passivation layer 303 and defines m number of second openings 304a, which correspond to m number of first openings 303a. The abovementioned first and second openings 303a and 304a are formed by the same laser scribe.

The back surface field regions 305 are defined at the first surface 3011, each of which corresponds to one of the m number of first openings 303a. The p-type dopant concentration of the back surface field regions 305 is greater than that of the p-type dopant for the semiconductor substrate 301. The formation of the back surface field regions 305 of the first surface 3011 relates to the fact that after aluminum paste had filled the first and second openings 303a and 304a, a firing process is utilized to form the back electrodes 306. During the firing process, aluminum atoms disperse into the first surface 3011 of the semiconductor substrate 301. Since aluminum and boron both belong to Group IIIA elements, local back surface field regions having higher concentration of p-type dopant are formed at contacting areas between the first surface 3011 and the back electrodes 306. These local fields are the back surface field regions 305 of the instant embodiment. The formation of the back surface field regions 305 of instant embodiment are reducing warping and fragmentations phenomenon after the firing process is over.

The back electrodes 306 are alternately arranged with one another, while making electrical contacts with the back surface field regions 305 via the first and second openings 303a and 304a. Any of the back electrodes 306 defines a center line C3 along the Y axis direction. Meanwhile, for the first openings 303a that correspond to the back electrodes 306, each of which defines a center line C2 along the Y axis direction. The distance between the centerlines C2 and C3 along the X axis direction does not go beyond 250 μm, while preferably not greater than 20 μm. Yet, the distance b between adjacent first openings 303a is a fixed value.

The second doping layer 307 is disposed on the second surface 3012, where the second doping layer 307 is doped with a second type dopant. For the instant embodiment, the second type dopant is an n-type dopant (e.g., phosphorus of Group VA elements). The second passivation layer 308 is disposed on the second doping layer 307 and defines a plurality of third openings 308a. The second anti-reflection layer 309 is disposed on the second passivation layer 308, where the second anti-reflection layer 309 defines a plurality of fourth openings 309a corresponding to the third openings 308a. The front electrodes 310 make electrical contact with the second doping layer 307 via the third and fourth openings 308a and 309a.

The first surface 3011 of the semiconductor substrate 301 for the solar cell 3 of the instant embodiment defines a center line CL parallel to the Y axis direction. The center lines C2 of adjacent first openings 303a are separated by a distance b, with b increases further away from the center line CL of the first surface 3011.

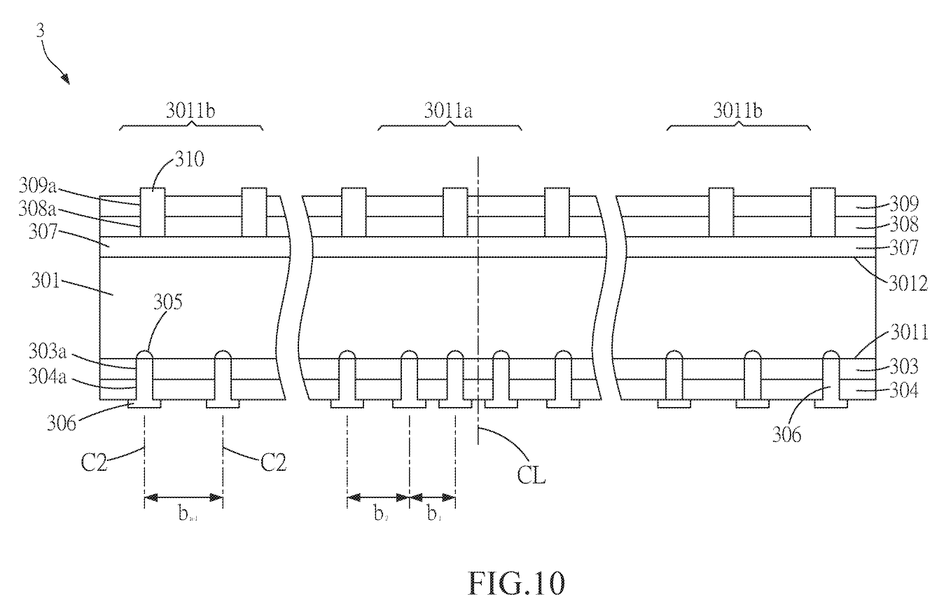

Please refer to FIG. 10, which shows a second sectional view of the solar cell of the instant disclosure. This figure depicts another configuration of the embodiment above. For the configuration illustrated by FIG. 10, the distance b between the center lines C2 of adjacent first openings 303a is not a fixed value, but rather increases linearly further away from the center line CL of the first surface 3011. For example, the first opening 303a closest to the center line CL of the first surface 3011 is labeled as numeral 1, and other first openings 303a toward the outer edges of the semiconductor substrate 301 along the X axis direction are labeled as numerals 2 , 3 . . . n−1, and n. Further, the distance between the first openings 303a labeled as numerals 1 and 2 is defined as b₁, the distance between the first openings 303a labeled as numerals 2 and 3 is defined as b₂, and so forth. The distance between the first openings 303a labeled as n−1 and n is defined as bₙ₋₁. Specifically, b₂−b₁ is equivalent to the unit distance Δs, b₃−b₁ is equivalent to the unit distance 2Δs, b₄−b₁ is equivalent to the unit distance 3Δs, and so forth. Further, starting with the first opening 303a off one side of the center line CL, the sum of the distance differences Δs between adjacent first openings 303a is equivalent to the largest distance s, that is to say Δs+2Δs+3Δs+ . . . +(n−2)Δs=largest distance s.

For another configuration, the first surface 3011 of the semiconductor substrate 301 defines a central region 3011a and two side regions 3011b. The two side regions 3011b are arranged on opposite sides of the central region 3011a along the X axis direction. Meanwhile, the central region 3011a extends along the Y axis direction to the edges 301e of the semiconductor substrate 301, where the surface area of the central region 3011a occupies one tenth to one third of the surface area of the first area 3011. Yet, the distance between the center lines C2 of adjacent first openings 303a on the side regions 3011b increases further away from the center line CL of the first surface 3011. However, the distance between the center lines C2 of adjacent first openings 303a of the central region 3011a remains substantially unchanged.

While the instant disclosure has been described by way of example and in terms of the preferred embodiments, it is to be understood that the instant disclosure needs not be limited to the disclosed embodiments. For anyone skilled in the art, various modifications and improvements within the spirit of the instant disclosure are covered under the scope of the instant disclosure. The covered scope of the instant disclosure is based on the appended claims.

What is claimed is:

1. A manufacturing method of back electrodes of a solar cell, comprising:
(a) providing a semiconductor substrate doped with a first type dopant, the semiconductor substrate has a first surface and a second surface opposite thereto, the first surface defines at least m number of first openings and m being an integer greater than 1, the first openings being arranged alternately along an X axis direction, the centers between adjacent first openings being separated by a first distance a;
(b) providing a screen defining at least m number of screen holes, the screen holes being alternately arranged along the X axis direction, the centers of adjacent screen holes being substantially separated by the first distance a, with the m number of screen holes corresponding to respective first openings;
(c) forming at least m number of back electrodes on the first surface via the screen;
(d) measuring a largest distance s defined along the X axis direction between the centers of the back electrodes and the centers of the first openings underneath; and
(e) adjusting a distance between the centers of adjacent first openings of another semiconductor substrate to be a second distance b according to the largest distance s, wherein the second distance b being greater than the first distance a.

2. The manufacturing method of claim 1, wherein the second distance b satisfies
$$b = a + \frac{2 s}{( m - 1 )} .$$

3. The manufacturing method of claim 1, wherein the second distance b ranges from 500 to 2500 μm.

4. The manufacturing method of claim 1, wherein the first surface of the other semiconductor substrate defines a central region and at least two side regions, with the two side regions arranged on opposite sides of the central region, and wherein in step (e), the distance between the centers of adjacent first openings of the two side regions is adjusted to the second distance b.

5. The manufacturing method of claim 4, wherein the central region extends along a Y axis direction to an edge of the other semiconductor substrate, with the two side regions arranged along the X axis direction on opposite sides of the central region, and wherein the surface area of the central region occupies one tenth to one third of the surface area of the first surface.

6. The manufacturing method of claim 4, wherein the second distance b ranges from 500 to 2500 μm.

7. The manufacturing method of claim 1, wherein the first surface defines a center line parallel to the Y axis direction, and the second distance b increases further away from the center line.

8. The manufacturing method of claim 1, wherein each back electrode defines a first center line along the Y axis direction, with the first openings corresponding to the back electrodes each defining a second center line along the Y axis direction, wherein the distance along the X axis direction between the first center line and the second center line is less than 250 μm.

9. The manufacturing method of claim 1, wherein the first openings are solid-line openings, dashed-line openings, dotted openings, or any combination thereof.

10. A solar cell, comprising:
a semiconductor substrate doped with a first type dopant, the semiconductor substrate having a first surface and a second surface opposite thereto;
a first passivation layer disposed on the first surface, the first passivation layer defining m number of first openings, with m being an integer greater than 1, the first openings being alternately arranged along an X axis direction;
a first anti-reflection layer disposed on the first passivation layer, the first anti-reflection layer defining m number of second openings corresponding to respective m number of first openings;
a plurality of back surface field regions at the first surface and corresponding to respective m number of first openings, the concentration of the first type dopant of the back surface field regions being greater than that of the first type dopant of the semiconductor substrate;
a plurality of back electrodes alternately arranged along the X axis direction, the back electrodes making electrical contact with respective back surface field regions via m number of second openings and m number of first openings, any of the back electrodes defining a first center line along a Y axis direction, the first openings corresponding to the back electrodes each defining a second center line along the Y axis direction, the first center line and the second center line being separated by a distance less than 50 μm;
a second doping layer disposed on the second surface, the second doping layer being doped with a second type dopant;
a second passivation layer disposed on the second doping layer;
a second anti-reflection layer disposed on the second passivation layer; and
a plurality of front electrodes making electrical contact with the second doping layer via the second anti-reflection layer and the second passivation layer.

11. The solar cell of claim 10, wherein the first surface defines a third center line parallel to the Y axis direction, and wherein the second center lines of adjacent first openings are separated by a second distance b, with the second distance b ranging from 500 to 2500 μm.

12. The solar cell of claim 11, wherein the second distance b increases further away from the third center line.

13. The solar cell of claim 10, wherein the first surface defines a third center line parallel to the Y axis direction and a central region and at least two side regions, with the central region extending along the Y axis direction to the edge of the semiconductor substrate, wherein the two side regions are arranged along the X axis direction on opposite sides of the central region, and wherein the surface area of the central region occupies one tenth to one third of the surface area of the first surface, with the second center lines of adjacent first openings of the two side regions being separated by a second distance b.

14. The solar cell of claim 13, wherein the second distance b ranges from 500 to 2500 μm.

15. The solar cell of claim 14, wherein the second distance b increases further away from the third center line.

16. The solar cell of claim 10, wherein the first openings are solid-line openings, dashed-line openings, dotted openings, or any combination thereof.
